(19) United States
(12) Patent Application Publication
(10) Pub. No.: US 2026/0208445 A1
(43) Pub. Date: Jul. 23, 2026

(54) ADDITIVE MANUFACTURING QUALITY CONTROL

(71) Applicant: Interspectral AB, Norrköping (SE)

(72) Inventor: Fredrik Johnson, Norrköping (SE)

(21) Appl. No.: 19/028,582

(22) Filed: Jan. 17, 2025

(51) Int. Cl. B29C 64/386; B33Y 50/00

(52) U.S. Cl. CPC B29C 64/386; B33Y 50/00

(57) ABSTRACT

In one general aspect, an additive manufacturing quality control method is disclosed in which physical property measurement data values are received from different spatial positions acquired for a three-dimensional part manufactured with an additive manufacturing process. The received physical property measurement data values are mapped into a three-dimensional arrangement of physical property measurement data voxels of differing sizes. And the quality of the three-dimensional part is evaluated based on evaluating the physical property measurement data voxels.

### CROSS-REFERENCE TO RELATED APPLICATION

This application is related to U.S. application Ser. No. 18/778,091, filed Jul. 19, 2024, to U.S. provisional application No. 63/527,808, filed Jul. 19, 2023, and to U.S. provisional application No. 63/655,892, filed Jun. 4, 2024. It is also related to PCT application No. PCT/EP2024/070639, filed Jul. 19, 2024. All of these documents are herein incorporated by reference.

### FIELD OF THE INVENTION

This invention relates to methods and apparatus for obtaining and processing information from additive manufacturing processes that can be used to understand, evaluate, and improve the quality of manufactured parts.

### BACKGROUND OF THE INVENTION

Additive manufacturing is a rapidly growing field that has the potential to revolutionize the manufacturing industry. However, ensuring the quality of the parts produced through additive manufacturing can be challenging due to the complexity of the process. Current quality control methods often rely on visual inspection or post-processing analysis, which can be time-consuming and expensive.

### SUMMARY OF THE INVENTION

In one general aspect, the invention features an additive manufacturing quality control method in which physical property measurement data values are received from different spatial positions acquired for a three-dimensional part manufactured with an additive manufacturing process. The received physical property measurement data values are mapped into a three-dimensional arrangement of physical property measurement data voxels of differing sizes. And the quality of the three-dimensional part is evaluated based on evaluating the physical property measurement data voxels.

In preferred embodiments, the mapping can map measurement data values from a plurality of different layers into individual physical property measurement data voxels of the first size with the mapping mapping measurement data values from a plurality of different layers into individual physical property measurement data voxels of the second size. The evaluating can evaluate the physical property measurement data voxels with a trained model. The method can further include receiving a set of physical property measurement data values from different spatial positions acquired for a plurality of three-dimensional parts manufactured with an additive manufacturing process, training a model with the received data set, with the evaluating evaluating the physical property measurement data voxels with the trained model. The training can include successively presenting the physical property measurement data values for successive ones of the plurality of three-dimensional parts in the set, and receiving feedback about the from the expert user for at least some of the plurality of three-dimensional parts in the set. The successively presenting can include successively presenting the physical property measurement data values for successive ones of the plurality of three-dimensional parts in the set in three dimensions using a graphical device, with the receiving feedback including receiving feedback from a three-dimensional annotation control. The method can further include continuing to train the model as parts are manufactured based after the initial training of the model. The evaluation can be performed in-situ during the additive manufacturing process. The evaluation can be performed after completion of the additive manufacturing process. The receiving physical property measurement data values from different spatial positions acquired for a three-dimensional part manufactured with an additive manufacturing process can receive physical property measurement data values from that include emitted radiation from a melt pool, measured laser power, and measured laser position. The receiving physical property measurement data values can receive physical property measurement data values from property measurements are in point-cloud format. The method can further include storing the three-dimensional arrangement of physical property measurement data voxels. The method can further include visualizing the stored three-dimensional arrangement of physical property measurement data voxels using a graphical device. The visualizing can provide a detailed representation of a final part, including any areas that deviate from desired quality standards. The method can further include storing the three-dimensional arrangement of physical property measurement data voxels in a file structure that includes a spatial tree. The method can further include storing the three-dimensional arrangement of physical property measurement data voxels in a sequence that is organized to allow efficient access and caching of information for proximate voxels.

In another general aspect, the invention features an additive manufacturing quality control system that includes an input for receiving physical property measurement data values from different spatial positions acquired for a three-dimensional part manufactured with an additive manufacturing process. The system also includes logic for mapping the received physical property measurement data values into a three-dimensional arrangement of physical property measurement data voxels in which a first set of the physical property measurement data voxels are voxels of a first size, and at least a second set of the physical property measurement data voxels are of a second size different from the first size. Storage is provided for storing the three-dimensional arrangement of physical property measurement data voxels, and an evaluation subsystem is operative to access and evaluate the stored three-dimensional arrangement of physical property measurement data voxels, and has a result output to report results of evaluating the three-dimensional arrangement of physical property measurement data voxels.

In a further general aspect, the invention features an additive manufacturing quality control system that includes means for receiving physical property measurement data values from different spatial positions acquired for a three-dimensional part manufactured with an additive manufacturing process, means for mapping the received physical property measurement data values into a three-dimensional arrangement of physical property measurement data voxels in which a first set of the physical property measurement data voxels are voxels of a first size, and at least a second set of the physical property measurement data voxels are of a second size different from the first size, means for storing the three-dimensional arrangement of physical property measurement data voxels, and means for accessing and evaluating the stored three-dimensional arrangement of physical property measurement data voxels, and having a result output to report results of evaluating the three-dimensional arrangement of physical property measurement data voxels. Mapping received physical property measurement data values into a three-dimensional arrangement of physical property measurement data voxels can help to detect defects that span across the layers that are deposited as the part is manufactured. This can help to detect defects that might otherwise be missed by existing non-destructive methods which generally apply a layer-by-layer focus. While these prior art systems can detect some types of issues by examining each layer individually, defects that develop gradually or span multiple layers may remain undetected. Detecting these additional defects can help increase the quality of parts manufactured by additive manufacturing methods.

Mapping received physical property measurement data values into a three-dimensional arrangement of physical property measurement data voxels can also allow data sets to be stored and operated on more efficiently. By using non-uniform voxel dimensions, the system can capture high-detail regions (e.g., critical areas) with finer granularity, while less critical regions can be assigned larger voxels, reducing computational overhead.

### BRIEF DESCRIPTION OF THE DRAWING

FIG. 1 is a block diagram of a manufacturing quality control system according to the invention;

FIG. 2 is a more detailed diagram of quality control portions of the system of FIG. 1;

FIG. 3 is a diagram illustrating operations performed by the system of FIG. 1;

FIG. 4 is a more detailed view of a quality measurement volume as shown in FIG. 3; and

FIG. 5 is a more detailed view of a quality result volume as shown in FIG. 3.

FIGS. 6A-F are diagrams that illustrate the operation of the system of FIG. 1 on an illustrative data set;

FIG. 7 is a diagram illustrating the operation of the system of FIG. 1 in more detail on subsets of the data set of FIG. 6;

FIG. 8 is a memory/cache diagram for the data subsets of FIG. 7;

FIG. 9 is a diagram summarizing an illustrative overall quality control operation for the system of FIG. 1;

FIG. 10 is a diagram summarizing the same illustrative overall quality control operation that is presented in FIG. 9, except that it uses larger voxel sizes to convey how using variable voxel sizes can affect the result data set,

FIG. 11 is a diagram showing sensor data being optimized for storage in a three-dimensional variable-voxel measurement data format;

FIG. 12A is a diagram of a first view of a user interface that allows the user to explore and annotate data; and

FIG. 12B is a diagram of a second view of the user interface that allows the user to explore and annotate data.

### DETAILED DESCRIPTION OF AN ILLUSTRATIVE EMBODIMENT

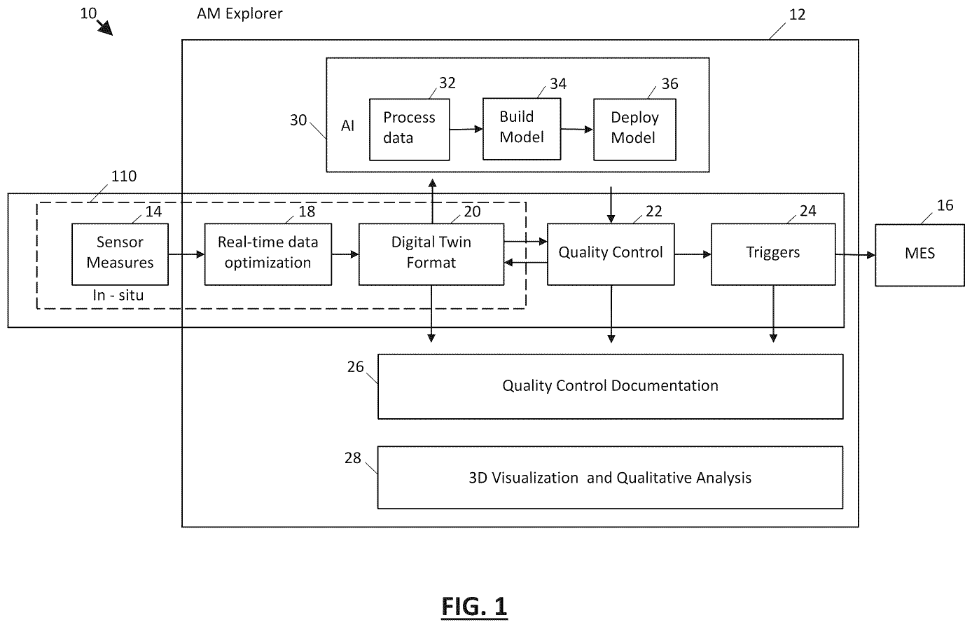

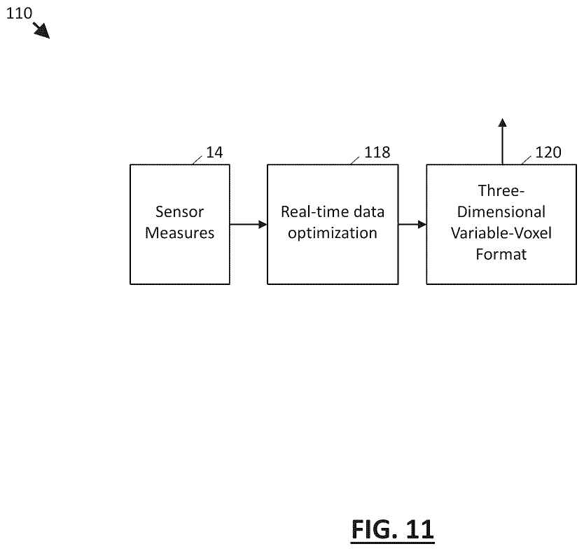

Referring to FIG. 1, an illustrative manufacturing quality control system 10 according to the invention includes a quality control and visualization system 12 that can receive sensor values 14 from an additive manufacturing process and provide build parameters to a manufacturing execution system 16. It can also include a real-time data optimization module 18 to optimize the received sensor values, and storage for these optimized values, which can be stored in digital twin format 20 and/or in a three-dimensional variable-voxel format 120 (see FIG. 11 and accompanying text). A quality control module 22 is operative to access the stored data and will be described in more detail below. A trigger detection module 24 is responsive to the quality control module and is operative to provide adjusted build parameters to the manufacturing execution system 16 based on quality evaluation information derived from the sensor values by the quality control subsystem.

The manufacturing quality control system 10 can also include an Artificial Intelligence (AI)-based quality control adjustment subsystem 30. This subsystem includes a data processing module 32 that can receive optimized sensor values. It can also include a model building module 34 that is operative to build models based on the optimized sensor values processed by the data processing module. A model deployment module 36 is responsive to the model building module to deploy new quality control models to the quality control module 22.

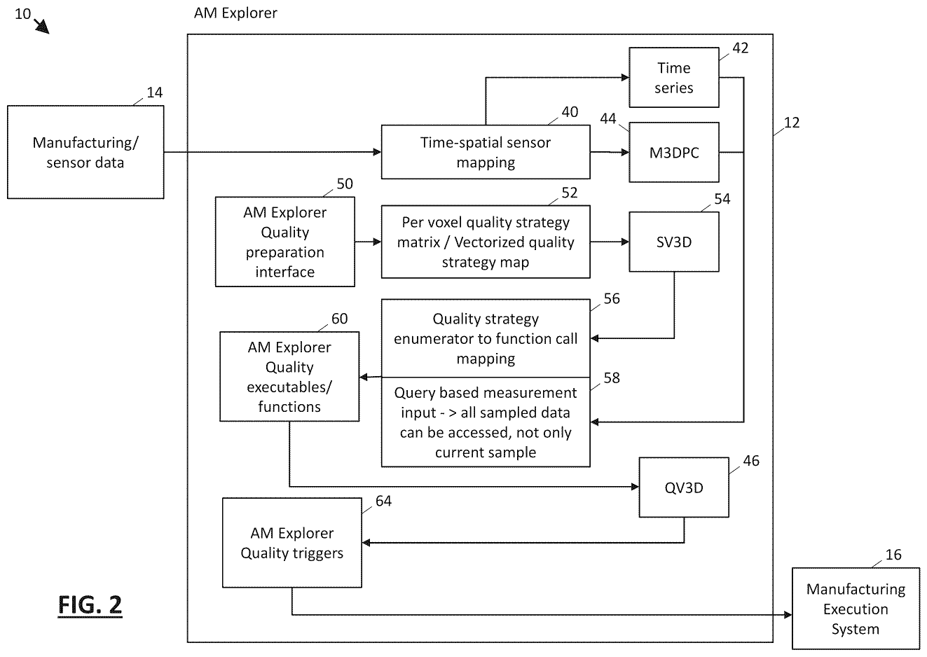

Referring to FIG. 2, the manufacturing quality control system 10 includes a time-spatial sensor mapping module 40 that receives the sensor values 14, and outputs them as a non-spatial time series (TS) 42 and a three-dimensional point cloud data set (PC3D) 44. The time series can contain sensor data which cannot be mapped to a point in space, air flow, chamber temperature, chamber pressure, humidity, but still affects the result of the three-dimensional point cloud data set. The time series data can also in some situations be used more efficiently in interpolations than the point cloud data can.

The manufacturing quality control system can also receive a voxel quality strategy matrix and vectorized quality strategy map from an additive manufacturing quality preparation interface, which may be operated by an end user through a manual user interface. The matrix and map are stored as a three-dimensional quality measurement volume (SV3D) 54. The system further includes a quality strategy enumerator to function cell mapping module 56 and a query-based measurement input module 58, which can access the latest sample or any previously measured sample that has been stored. A quality evaluation module 60 applies quality executables and functions to the output of these blocks, and the resulting data is stored as a three-dimensional result data set (QV3D) 46.

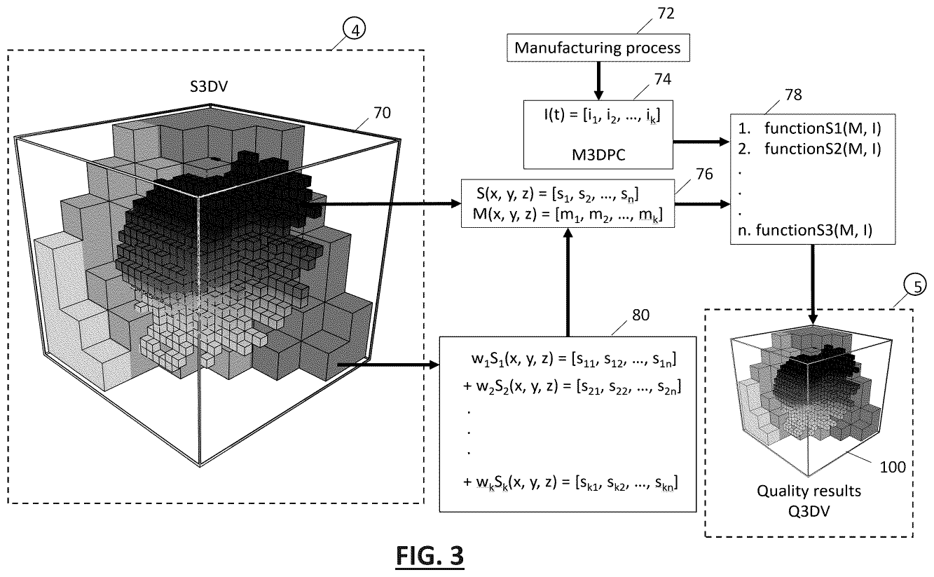

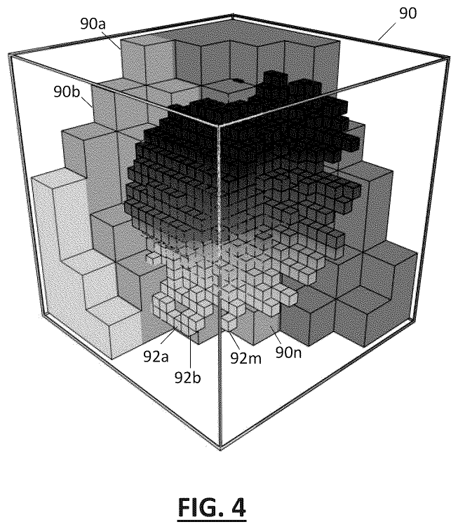

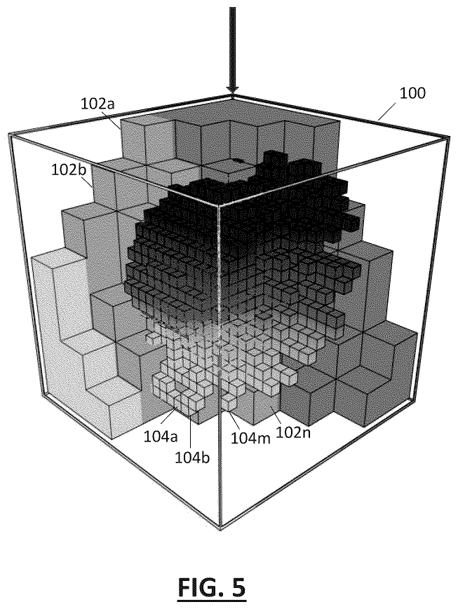

Referring to FIGS. 1-5, the manufacturing quality control system 10 stores the three-dimensional measurement volume in a three-dimensional format 70 that includes voxels of two or more different sizes, such as larger voxels 90a, 90b, . . . 90n and smaller voxels 92a, 92b, and 92n (76). And each of these voxels is associated with one quality measure or preferably a vector of quality measures [S₁, S₂, Sᵢ] and a quality evaluation method or preferably a vector of quality evaluation methods [M₁, M₂, Mⱼ]. The system applies (78) these measures and methods to the sensor data (74) to obtain a three-dimensional result data set 100. The result data set can also include voxels of two or more different sizes, such as larger voxels 102a, 102b, . . . 102n and smaller voxels 104a, 104b, and 104n (76). The vectors can include parameters used in the functions in each voxel. These parameters can for example control how functions sample in previously collected data or evaluated data.

In one general aspect, operation of the manufacturing quality control system 10 includes the following steps:
Measuring material deposition properties or powder bed fusion properties together with other process measures during the additive manufacturing process. The measurements can be taken using sensors or other suitable devices and can include data such as temperature, laser power, and speed.
Saving the measured data in a structured 3D point cloud. The point cloud can be stored in a database or other suitable storage medium and can be used for further analysis and evaluation.
Defining a quality measure strategy as a 3D volume. The quality measure strategy can be predefined based on the desired quality of the parts produced through additive manufacturing. Each voxel in the 3D volume can contain a vector of quality measures and vector of quality evaluation methods represented as an enumerator.
Defining the 3D volume in different levels of detail. The levels of detail can vary based on the desired resolution and accuracy of the quality evaluation. In lower levels of detail (larger voxels), the down-sampling of the quality evaluation methods can be performed by using weighted averages of the contributing voxels, for example, using bicubic interpolation. Lower levels of detail enable faster quality evaluation, but less precision.
Evaluating the 3D point cloud against the 3D volume continuously. The evaluation can be performed using suitable algorithms and can provide real-time feedback on the quality of the parts being produced. The evaluation can also be performed at different levels of detail based on the resolution and accuracy of the 3D volume.

In addition to the features described earlier, the quality control approach for additive manufacturing described in this document can include a 3D point cloud that represents the ideal laser path or material deposition nozzle path. This 3D point cloud can be generated using computer-aided design (CAD) software and can represent the optimal path for the laser or nozzle to follow during the manufacturing process. During or after the actual manufacturing process, the measured 3D point cloud positions can be compared against this ideal path and create a measure that can be used by methods defined in the quality 3D volume to detect any deviations or defects in the final part.

The 3D point cloud representing the ideal laser path can be used in combination with the predefined quality measure strategy defined as a 3D volume to provide a comprehensive evaluation of the additive manufacturing process. By continuously evaluating the 3D point cloud against the 3D volume, any areas of the part that deviate from the desired quality standards can be detected, allowing for immediate feedback and adjustments to the manufacturing process.

The use of a 3D point cloud representing the ideal laser path can provide additional benefits, including:
Improved part accuracy and consistency: By comparing the actual manufacturing process against the ideal laser path, this approach can ensure that each part is produced with high accuracy and consistency.
Reduced material waste: By minimizing deviations and defects in the final part, this approach can reduce the amount of material waste generated during the manufacturing process.
Increased design flexibility: The use of a 3D point cloud representing the ideal laser path can allow for increased design flexibility, as this approach can adapt to complex and intricate designs while maintaining high quality standards.

The addition of a 3D point cloud representing the ideal laser path to the quality control process for additive manufacturing described in this document can provide additional benefits and improve the overall quality of the final part.

Systems and methods according to the invention can be used with various types of additive manufacturing processes, including powder bed fusion, directed energy deposition, and material extrusion. They can also be used with various types of materials, including metals, polymers, and composites.

Systems and methods according to the invention can provide various benefits, including:
Real-time quality control: Systems and methods according to the invention can enable real-time monitoring and evaluation of the additive manufacturing process, allowing for immediate feedback and adjustments if necessary.
Reduced production time and cost: By ensuring high-quality parts with minimal defects, systems and methods according to the invention can reduce the need for post-processing and rework, resulting in reduced production time and cost.
Improved part performance: Systems and methods according to the invention can ensure that parts produced through additive manufacturing meet desired quality standards, resulting in improved part performance and reliability.

In one embodiment, a machine learning component can also be included that uses the 3D point cloud and 3D volume data to train a predictive model for quality control. The predictive model can be used to predict the quality of parts produced in future additive manufacturing processes based on past data, allowing for proactive quality control and process optimization.

In another embodiment, systems and methods according to the invention can include a feedback loop that allows for the adjustment of the 3D volume based on the results of the evaluation. For example, if the evaluation reveals a specific area of the part that consistently fails to meet quality standards, the 3D volume can be adjusted to increase the resolution and accuracy of the quality evaluation in that area.

Systems and methods according to the invention can be implemented using suitable software and hardware components, including sensors, 3D scanning devices, and computing devices capable of processing and analyzing large amounts of data.

After the quality control process is completed, the result can be visualized in 2D or 3D using a graphical device, such as a computer monitor or a virtual reality headset. The visualization can provide a detailed representation of the final part, including any areas that deviate from the desired quality standards.

The use of a graphical device to visualize the quality control results can provide several benefits, including:
Enhanced understanding of the manufacturing process: Providing a visual representation of the manufacturing process can help users better understand the process and identify areas for improvement.
Improved communication between stakeholders: The use of a graphical device can facilitate communication between different stakeholders involved in the manufacturing process, including designers, engineers, and manufacturers.
Real-time feedback and adjustments: Providing real-time feedback on the manufacturing process can allow for immediate adjustments and improvements to the process.

The graphical device can be configured to display the quality control results in a variety of formats, including 2D images, 3D models, and virtual reality simulations. The format used can be selected based on the needs of the user and the specific requirements of the manufacturing process.

Methods and apparatus for additive manufacturing quality control have been disclosed. In particular embodiments, these involve measuring physical properties of the additive manufacturing process and saving the measured data in a 3D point cloud, called PC3D. The measured properties can be material deposition temperature, melt pool temperature, speed and position laser or nozzle. As an example, in laser powder bed fusion, the measured property can be the emitted radiation from the melt pool, the measured laser power and the measured laser position. As an example, in fused deposition modelling, the measured property can be the emitted heat radiation from the filament deposition nozzle, the measured deposition speed and the measured position of the nozzle. Also disclosed is a predefined quality measure strategy defined in a 3D volume, called SV3D, where each voxel can contain a vector of quality measures and a vector of enumerated quality evaluation methods. The SV3D can be defined in different levels of detail, and in lower levels of detail, the down-sampling of the quality evaluation methods is performed by adding the methods of the contributing voxels and assigning each a weight that can be used to calculate the final quality measure by interpolation. The measured data in the PC3D can be evaluated by using it as input to the quality measures and evaluation methods defined in SV3D. This can be performed after the manufacturing process is completed or, in-situ, during manufacturing. When used in-situ, the sampled PC3D point cloud is evaluated against the SV3D volume continuously to ensure high-quality parts with minimal defects are produced. The level of detail and the vectors of SV3D can be changed, either manually or automatically during the manufacturing process as a result of previously evaluated quality or external arbitrary processes. The result of the quality evaluation is saved into a 3D volume, called QV3D, that can, but need not be of the same resolution as SV3D.

The present invention can provide an approach for additive manufacturing quality control that addresses the challenges associated with ensuring the quality of parts produced through additive manufacturing. This involves measuring material deposition properties or powder bed fusion properties together with other process measures during the additive manufacturing process and saving the measured data as a 3D point cloud. It also includes a predefined quality measure strategy defined as a 3D volume, where each voxel can contain a vector of quality measures and vector of quality evaluation methods associated with the voxel. The 3D volume can be defined in different levels of detail, and in lower levels of detail, the down-sampling of the quality evaluation methods is performed by using weighted interpolation of the contributing voxels, for example, using bicubic interpolation. This approach evaluates the 3D point cloud against the 3D volume continuously to ensure high-quality parts with minimal defects are produced.

Manufacturing quality control systems and methods according to the invention can use a variety of different types of data for a part that is designed to be manufactured using additive manufacturing techniques. These data can include sensor values for a number of different types of physical quantities, including physical parameters such as temperature or humidity; process parameters, such as laser power; and visual information, such as image data from a camera or scanner. These can be received in a variety of forms, including individual sensor signals or data files that store information for positions in one, two, three or more dimensions.

The quality control operations can be performed in-situ on data being generated as a part as it is manufactured. It can also be applied afterwards to data acquired during manufacturing. Or it can be applied to data for the part acquired after manufacturing, such as CT scan data. It may even be applicable to data files before the manufacturing process has begun. Results from these different stages can be compared and combined in any combination. It may for example be interesting to compare pre-printing design data with actual post-printing tomography data, in order to evaluate if the manufactured product has turned out as planned. It may also be interesting to compare pre-printing design data with actual data acquired during the additive manufacturing process, regarding for example the trajectory of the laser, to evaluate whether the planned laser trajectory has in fact been followed during the additive manufacturing process.

### EXAMPLE

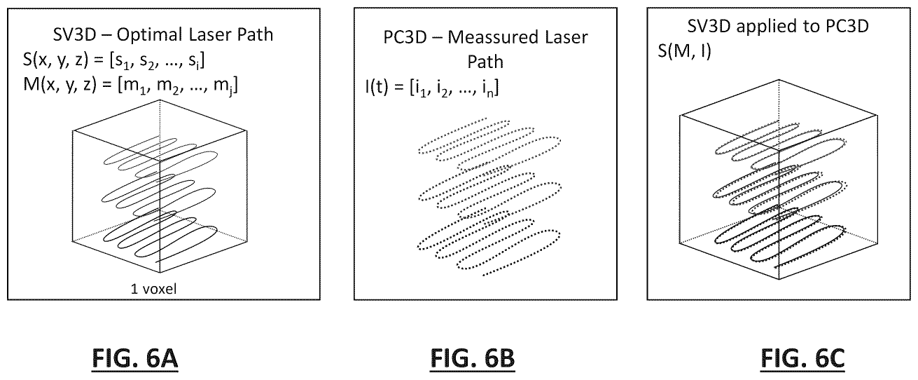

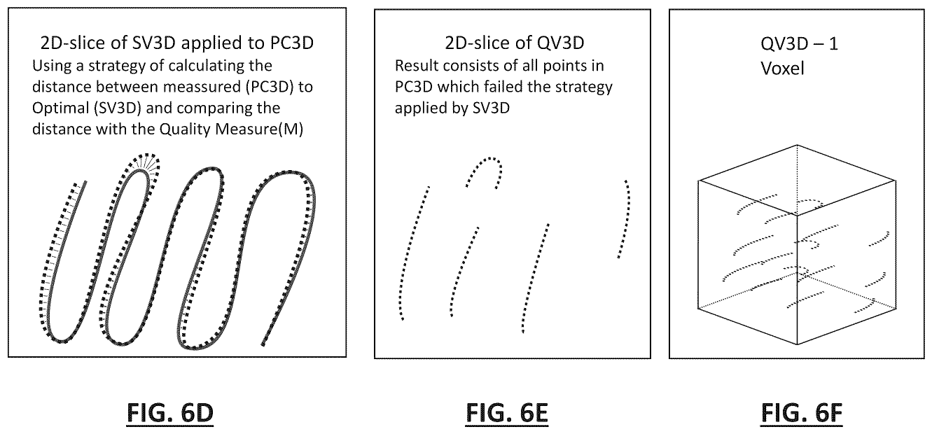

In an illustrative operation, referring to FIGS. 6A-6F, a point cloud quality measure strategy data set SV3D is first defined for an optimal laser path to manufacture a part (FIG. 6A). The initial path specification can be obtained in various ways, such as through the use of a CAD system.

A measured laser path PC3D is acquired from the manufacturing of a particular part (FIG. 6B), as well. The quality measure strategy data set SV3D, is then applied to the measured path (FIG. 6C). In this process, a 2D-slice of the quality measure strategy data set SV3D is applied to PC3D using a strategy of calculating the distance between measured (PC3D) to Optimal (SV3D) and comparing the distance with the Quality Measure (M) (FIG. 6D). The result is a 2D-slice result set slice that consists of all points in the measured data path PC3D which failed the strategy applied by the quality measure strategy data set SV3D. Together the 2D slices are stored as a three-dimensional result data set QV3D (Fig. FIG. 6E). This data set can be used to diagnose process issues or inform adjustments to the process inputs. It can also be used as training data in a machine learning process to optimize the ideal path to be used to manufacture future parts.

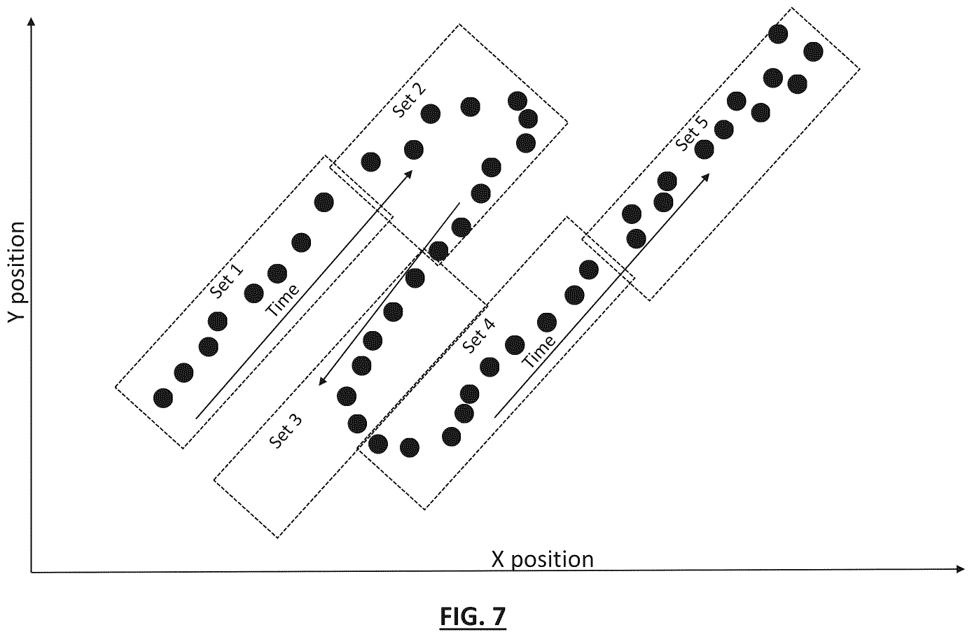

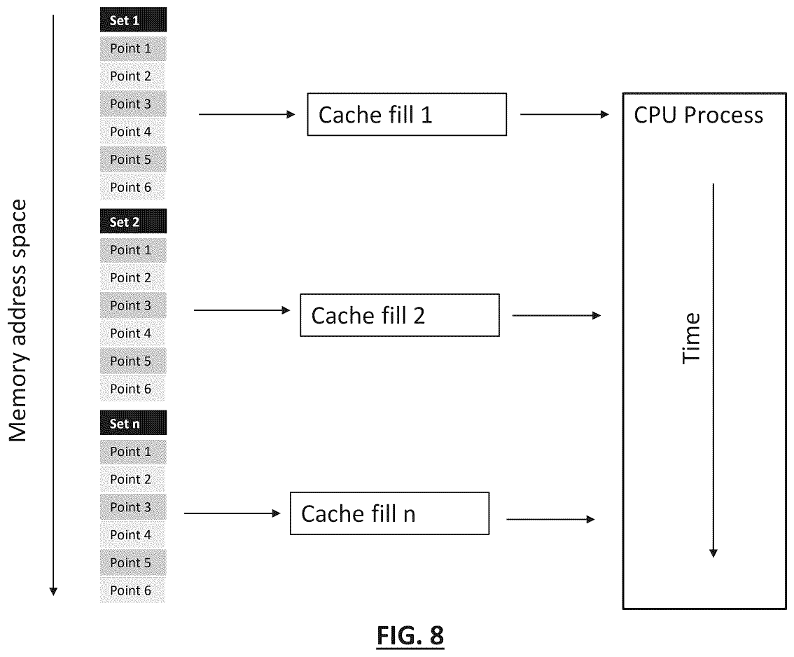

Referring to FIGS. 7 and 8, the point cloud structure is preferably structured for fast search queries. By using the laser/nozzle path, which is usually known in advance, the point cloud structure can be structured so that search during manufacturing is fast by reducing both cache misses and the need for time consuming search patterns. Points that are likely to be searched for during a given time should be stored close to each other in memory. Data can be split into different files to simplify threaded searches and help with distributing exceptionally large datasets over several memory devices. In some implementations processing can be distributed over several computer systems connected via a network. Data can be split into chunks that can be transferred and processed together to make transfer more effective and reduce cache misses. The data can be structured so that it is suited for processing on a graphics processing unit. Other volumetric structures used by the system are preferably also structured for efficient access in this way.

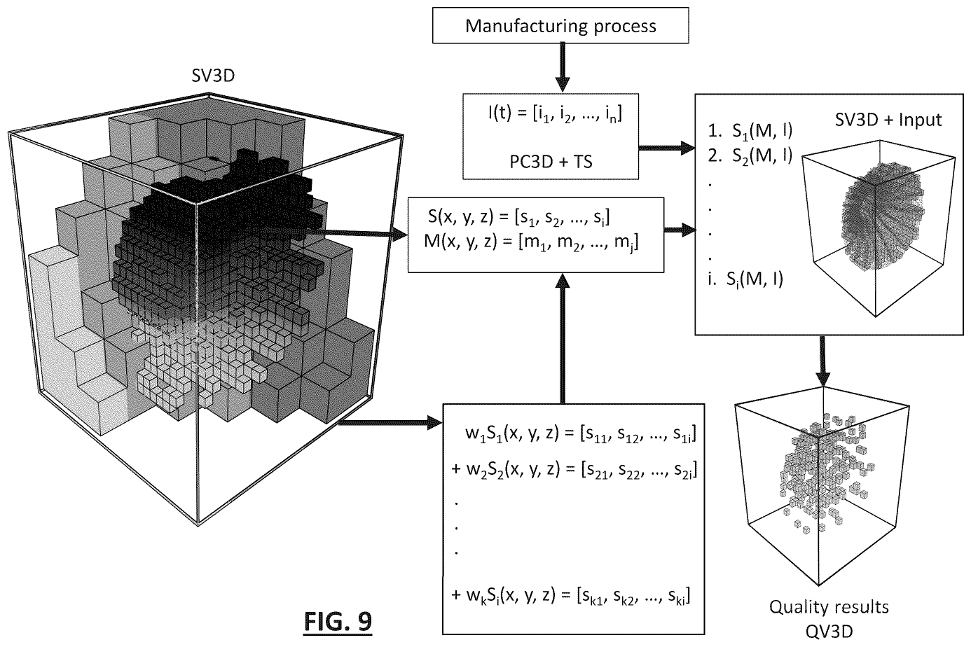

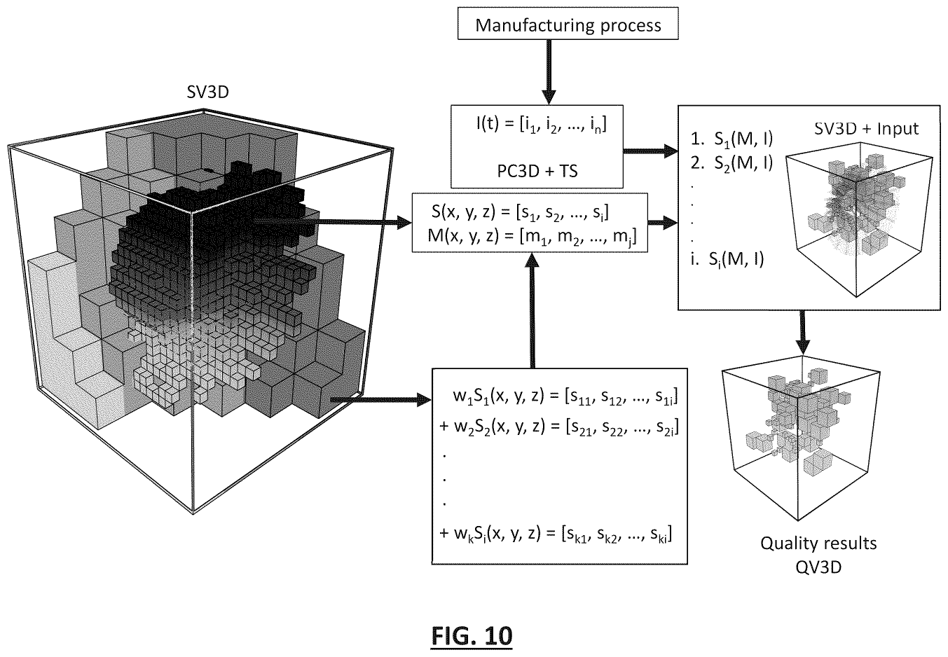

FIGS. 9 and 10 visually summarize an illustrative instance of the overall quality control process. FIG. 10 differs from FIG. 9 in that it uses a quality measure strategy data set SV3D with a mixture of voxel sizes that includes some larger ones. This leads to a three-dimensional result data set QV3D that also includes some larger voxels.

The multi-sixed voxel volumes can be stored in several ways, such as using a spatial tree structure. Each voxel represents a part of memory with its associated strategy functions coupled with quality values. To optimize speed while reducing errors such as cache misses, it should be stored in such a way where it aligns according to a specific voxel probability to be read and used in memory. This way of approach to storage provides a good foundation for multi-threading access and fast rendering.

For example, one instance of a quality measure strategy data set SV3D might be stored using a well-known octree data structure, which can efficiently manage spatial data in three dimensions. A root voxel encapsulates the entire dataset's bounding volume. By using recursive subdivision, an octree divides a three-dimensional space into smaller, more granular voxels, where each voxel contains the associated quality evaluation strategy. This tree can updated and restructured according to the results of the evaluation.

Referring to FIGS. 1 and 11, the sensor data can also be optimized 118 for storage in a three-dimensional variable-voxel measurement data format 120, in addition to or instead of in the digital twin format 20. This format includes a mixture of voxels of different sizes, in a manner similar to the formats used for the quality measure strategy data set SV3D and three-dimensional result data set QV3D, but the measurement data voxels do not need to exhibit the same distribution of voxel sizes as these data sets.

The three-dimensional variable-voxel measurement data set can be constructed from received measurement data on the fly or from an earlier-acquired measurement data set. This operation can be performed by adjusting voxel sizes as features of interest are detected in the measurement data set. Areas of closely spaced laser points, and areas in which additional material is added to successively higher layers to produce overhangs can both be assigned to smaller voxels. Conversely, more even features and sparse areas can be assigned to larger voxels. Other features of interest could also be detected, and the feature set selected may depend on experience with the manufacturing technique and material used. The voxels generally include data from more than one layer, so the construction of the three-dimensional variable-voxel measurement data set is an ongoing process that is based on a sliding subset of the measurement data that spans more than one layer.

In one embodiment that can be used for a powder bed fusion manufacturing process, the system creates a three-dimensional volume using sensor data collected from a 3D printer in real time. As the printer operates, a sensor (for instance, one attached to a laser that melts powder to form each layer) provides measurement data that is mapped onto the evolving volume. Unlike many standard volumetric approaches, the system's voxels do not remain fixed in size; instead, they can be subdivided dynamically based on several criteria.

Because both the sensor's frequency (in Hz) and the average speed at which it traverses the print area are known, the system can detect when sensor readings are clustered close together. If the laser is moving slowly in a corner or over a detailed region, for example, the sensor points land in a smaller area, indicating a need for higher granularity. To capture more detail, voxels are subdivided in these regions.

Certain shapes, like an overhanging slope or upside-down pyramid, are known to be prone to errors in the printing process. When the system notices that the printer is building one of these shapes, therefore, it devotes extra voxel subdivisions to capture finer detail and thus gain a better understanding of potential problem areas.

Before printing begins, the system can examine the base 3D model to anticipate where to subdivide the volume more heavily. While this “preparation pass” is not definitive, because the real sensor data will ultimately determine the voxel size, it helps identify regions likely to need higher resolution.

Although the system employs dynamically sized voxels to capture finer details in areas of interest, they shouldn't be made too small. This is because the AI analyzing the data needs to maintain a “big-picture” view of the entire print. Letting the AI focus on the whole volume at once can be very demanding in terms of hardware and processing constraints. A more reasonable approach is to concentrate on individual regions (with more finely subdivided voxels) and then combine those detailed insights to reconstruct the entire volume. This tradeoff helps to capture localized detail without overwhelming system resources or losing broader context.

In one embodiment that employs a 1 micron measurement spacing, the process starts with a 1 mm×1 mm×1 mm voxel. The system then monitors the number of sensor readings in each voxel as data is received. The voxels are made smaller when this number is found to be above an expected maximum threshold, and they are made bigger when the number is found to be below an expected minimum threshold. To detect overhangs, inverted pyramids and other similar structural features of interest, a comparison is made with measurements in lower layers. Comparisons can therefore take place in each of the three dimensions, so that the length, width, and height of the voxels can evolve differently over time.

Throughout the printing process, and after completion if needed, the collected data can be re-evaluated and voxel subdivisions adjusted to reflect changes in sensor readings or the detection of potential error-prone regions. This ensures that as much detail as possible is captured without sacrificing an overview that the AI requires for effective analysis.

In one embodiment, the three-dimensional variable-voxel format is based on a file format in which the variably-sized voxels are arranged in a tree structure, and each voxel field holds the measurement values that it covers, such as a in an array. These values can then be averaged, interpolated, and/or otherwise processed to derive one or more aggregate measurement values for that voxel.

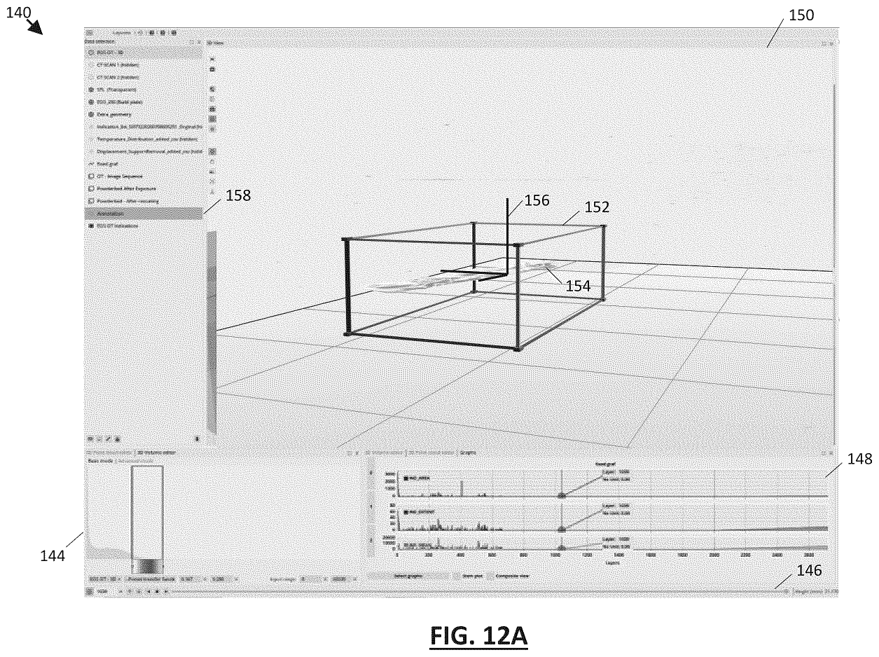

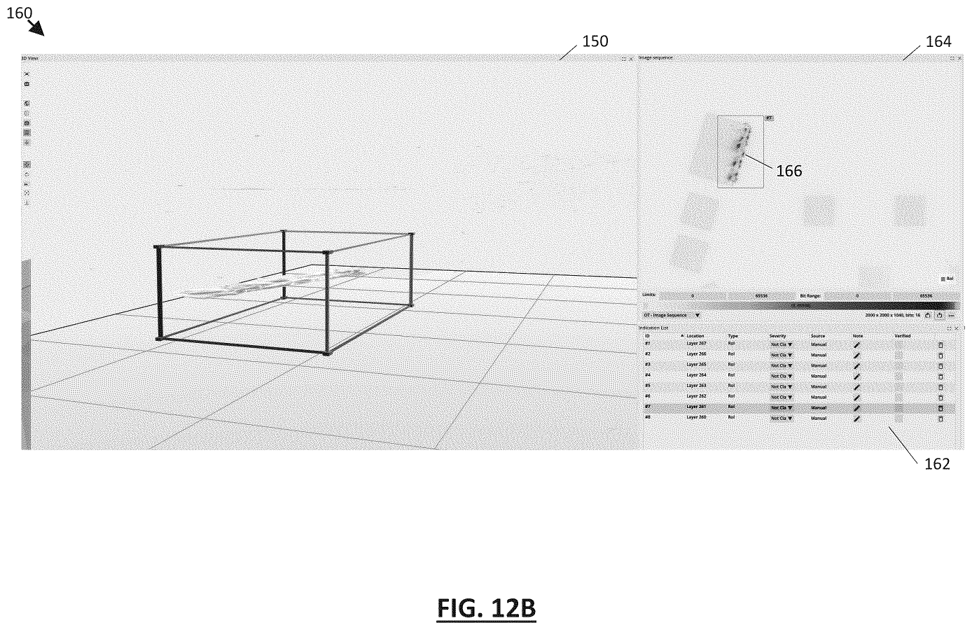

Referring to FIGS. 12A and 12B, the system 10 presents a user interface that allows the user to explore and annotate the data. In a first view 140, the user interface includes a sidebar navigation control 142, a histogram control 144, a layer selection slider 146, and a measurement data graph viewing window 148. These reference and operate on a workspace area 150 that allows the user to select and work with a volume of interest that can be contained in a bounding box 152. This volume of interest can include defect areas 154 flagged by AI or another user. A user can also flag and annotate defects by selecting an annotation control 158 and then using a cursor 156 to identify them. The cursor can include short lines in the x, y, and z directions to aid in navigation.

In a second view 160, the user interface can include a feature/defect selection control 162 and a feature/defect viewing area 164 that allows a user to more closely examine details 166 of defects selected by the selection control. Defects are typically found in areas of high frequency, and the histogram control can therefore help to filter the data to locate them. The views in this embodiment are also color coded to show frequency. The workspace can in addition simultaneously display the CAD model data coded as a low-frequency for the part being built along with these features as a reference (not shown in workspace areas for clarity).

The annotation control can be used by expert users to train AI models to be used to evaluate the data in the three-dimensional variable-voxel measurement data set. To accomplish this, an expert user works with the user interface controls to explore the data and flag areas that he or she identifies as exhibiting a defect. This model training can be performed in advance of actual manufacturing runs on a series of data sets for earlier product runs, and it can be optionally updated as more parts are built. Models used by the system can be also be trained in other ways, such as using the PyTorch framework (pytorch.org) or the ONNX format (onnx.ai).

The system described above has been implemented in connection with special-purpose software programs running on general-purpose computer platforms, but it could also be implemented in whole or in part using special-purpose hardware. The system can further be implemented in connection with a cloud-based or otherwise virtualized environment, and its functionality can be provided to end users as stand-alone software distributions or in software-as-a-service format. Moreover, different entities can develop and operate different parts of the system.

The system can also be broken into the series of modules and steps shown for illustration purposes, one of ordinary skill in the art would recognize that it is also possible to combine them and/or split them differently to achieve a different breakdown, and that the functions of such modules and steps can be arbitrarily distributed and intermingled within different entities, such as routines, files, and/or machines.

The present invention has now been described in connection with a number of specific embodiments thereof. However, numerous modifications which are contemplated as falling within the scope of the present invention should now be apparent to those skilled in the art. Therefore, it is intended that the scope of the present invention be limited only by the scope of the claims appended hereto. In addition, the order of presentation of the claims should not be construed to limit the scope of any particular term in the claims.

What is claimed is:

1. An additive manufacturing quality control method for a processor and a storage device including instructions configured to run on the processor, including:
receiving physical property measurement data values from different spatial positions acquired for a three-dimensional part manufactured with an additive manufacturing process,
mapping the received physical property measurement data values into a three-dimensional arrangement of physical property measurement data voxels in which a first set of the physical property measurement data voxels are voxels of a first size, and at least a second set of the physical property measurement data voxels are of a second size different from the first size, and
evaluating the quality of the three-dimensional part based on evaluating the physical property measurement data voxels.

2. The method of claim 1 wherein the mapping maps measurement data values from a plurality of different layers into individual physical property measurement data voxels of the first size and wherein the mapping maps measurement data values from a plurality of different layers into individual physical property measurement data voxels of the second size.

3. The method of claim 1 wherein the evaluating evaluates the physical property measurement data voxels with a trained model.

4. The method of claim 1 further including receiving a set of physical property measurement data values from different spatial positions acquired for a plurality of three-dimensional parts manufactured with an additive manufacturing process, training a model with the received data set, and wherein the evaluating evaluates the physical property measurement data voxels with the trained model.

5. The method of claim 4 wherein the training includes successively presenting the physical property measurement data values for successive ones of the plurality of three-dimensional parts in the set, and receiving feedback about the from the expert user for at least some of the plurality of three-dimensional parts in the set.

6. The method of claim 5 wherein the successively presenting includes successively presenting the physical property measurement data values for successive ones of the plurality of three-dimensional parts in the set in three dimensions using a graphical device, and wherein the receiving feedback includes receiving feedback from a three-dimensional annotation control.

7. The method of claim 4 further including continuing to train the model as parts are manufactured based after the initial training of the model.

8. The method of claim 1 wherein the evaluation is performed in-situ during the additive manufacturing process.

9. The method of claim 1 wherein the evaluation is performed after completion of the additive manufacturing process.

10. The method of claim 1 wherein the receiving physical property measurement data values from different spatial positions acquired for a three-dimensional part manufactured with an additive manufacturing process receives physical property measurement data values from that include emitted radiation from a melt pool, measured laser power, and measured laser position.

11. The method of claim 1 wherein the receiving physical property measurement data values receive physical property measurement data values from property measurements are in point-cloud format.

12. The method of claim 1 further including storing the three-dimensional arrangement of physical property measurement data voxels.

13. The method of claim 12 further including visualizing the stored three-dimensional arrangement of physical property measurement data voxels using a graphical device.

14. The method of claim 13 wherein the visualizing provides a detailed representation of a final part, including any areas that deviate from desired quality standards.

15. The method of claim 1 further including storing the three-dimensional arrangement of physical property measurement data voxels in a file structure that includes a spatial tree.

16. The method of claim 1 further including storing the three-dimensional arrangement of physical property measurement data voxels in a sequence that is organized to allow efficient access and caching of information for proximate voxels.

17. An additive manufacturing quality control system, including:
an input for receiving physical property measurement data values from different spatial positions acquired for a three-dimensional part manufactured with an additive manufacturing process,
logic for mapping the received physical property measurement data values into a three-dimensional arrangement of physical property measurement data voxels in which a first set of the physical property measurement data voxels are voxels of a first size, and at least a second set of the physical property measurement data voxels are of a second size different from the first size,
storage for storing the three-dimensional arrangement of physical property measurement data voxels, and
an evaluation subsystem operative to access and evaluate the stored three-dimensional arrangement of physical property measurement data voxels, and having a result output to report results of evaluating the three-dimensional arrangement of physical property measurement data voxels.

18. An additive manufacturing quality control system, including:
means for receiving physical property measurement data values from different spatial positions acquired for a three-dimensional part manufactured with an additive manufacturing process,
means for mapping the received physical property measurement data values into a three-dimensional arrangement of physical property measurement data voxels in which a first set of the physical property measurement data voxels are voxels of a first size, and at least a second set of the physical property measurement data voxels are of a second size different from the first size,
means for storing the three-dimensional arrangement of physical property measurement data voxels, and
means for accessing and evaluating the stored three-dimensional arrangement of physical property measurement data voxels, and having a result output to report results of evaluating the three-dimensional arrangement of physical property measurement data voxels.
